(19) United States
(12) Patent Application Publication
(10) Pub. No.: US 2015/0104562 A1
(43) Pub. Date: Apr. 16, 2015

(54) Method Of Manufacturing Multilayer Interconnects For Printed Electronic Systems

(71) Applicants: Harish Subbaraman, Austin, TX (US); Ray T. Chen, Austin, TX (US)

(72) Inventors: Harish Subbaraman, Austin, TX (US); Ray T. Chen, Austin, TX (US)

(73) Assignee: OMEGA OPTICS, INC., Austin, TX (US)

(21) Appl. No.: 14/050,338

(22) Filed: Oct. 10, 2013

(51) Int. Cl. H05K 3/46

(52) U.S. Cl. CPC H05K 3/4664; H05K 3/4673; H05K 2203/166
USPC 427/8; 427/97.1; 427/553; 427/97.3; 427/97.4; 427/97.6

(57) ABSTRACT

A fully additive method for forming multilayer electrical interconnects for printed electronic and/or optoelectronic devices is disclosed. Electrical interconnects are fabricated by directly ink-jet printing a dielectric material with selective interconnection holes, and then ink jet printing conductive patterns and filling the interconnection holes with conductive material to form multilayer interconnects. A method for manufacturing a multilayer printed electronic system utilizing the invention is also disclosed. Other embodiments are described and claimed.

### I. BACKGROUND

1. Field Of The Invention

The present disclosure relates generally to the field of electronics, and more specifically to an additive method for forming multilayer interconnections in printed electronic circuits.

2. Background of the Invention

The statements in this section merely provide background information related to the present disclosure and may not constitute prior art.

Multilayer interconnects are extremely critical for current electronic systems which include hundreds and thousands of electronic components on a single substrate. It is impossible to achieve interconnection between different components within the same layer without two interconnection lines crossing over. The crossing over of interconnection lines leads to unintended short circuits or crosstalk, and needs to be avoided.

Traditionally, semiconductor and PCB circuit manufacturers have relied on the use of conventional photolithography and developing in order to open ‘via’ holes in a dielectric layer at the intended locations on the substrate. Metallization is then performed in order to fill selective via holes, thus achieving interconnection between different components on the substrate.

Methods currently used to create via holes in plastic flexible electronics rely on conventional photolithography; laser milling to directly form a via hole; or molds to form an impression of the via holes in a liquid resist, followed by etching of the residual layer using plasma etching. In all of these methods, removal of material is unavoidable, thus not making it possible to prevent waste of expensive material.

For printed electronics, it is extremely important to eliminate material wastage in order to keep the cost low enough for profitability. Alternatively, an all additive process can eliminate the use of chemicals for removal of materials, thus providing facile routes for developing printed electronic systems with low cost and without the harmful effects of etching.

In one previous method, a dielectric material was ink jet printed only at the crossing point of two metal interconnects, such that the dielectric material was sandwiched between the two metal interconnects. This enabled the crossing of the top interconnect line over the bottom interconnect line without causing a short circuit. Although this method provides an alternative additive method for forming multilayer interconnects, it is extremely difficult to scale to more than two layers.

### II. SUMMARY

An additive method for fabricating multilayer interconnects for printed electronic devices is presented.

An aspect of the present invention provides a method of manufacturing multilayer interconnects on a substrate already containing electronic devices and alignment marks, including, forming a dielectric coating with interconnection holes; depositing a liquid conductive material on top to form interconnection lines and filling the interconnection holes; and repeating the process of dielectric coating with interconnection holes and filling the hole with the conductive material in order to build up a multilayer interconnection.

The substrate may comprise any rigid or flexible material, such as metal, a printed circuit board, plastic, wood, glass, semiconductor wafer, paper, or clothing. The rigid substrate may assume any shape. The flexible substrate may be in the form of a sheet or in the form of a roll. The substrate may comprise electronic circuitry on the backside, embedded within, or on top of the substrate, wherein the electronic circuitry is configured to transmit electrical signals. The substrate may comprise complete integrated optoelectronic circuitry on the backside, embedded within, or on top of the substrate, wherein the optoelectronic circuitry is configured to transmit both electrical and optical signals. Electronic devices may be developed on top of the substrate using printing techniques. In the present invention, the alignment marks may comprise metal, dyes, color pigments, etc. which turn opaque upon hardening and may be patterned into any shape and size. The first dielectric layer on top of the first electronic layer may comprise any liquid dielectric material solution, such as SU8-2002 (SU8) polymer from MicroChem Corp., that may be hardened through the use of any of the plurality of curing methods, including but not limited to, heating; exposing to UV radiation; exposing to high power, short light pulses; or air drying. The forming of the first dielectric layer may comprise: utilizing alignment marks on the substrate for determining position; ink jet printing the liquid dielectric material solution in a desired pattern on the substrate to create interconnection holes in desired locations; and hardening the first dielectric layer to permanently retain the interconnection holes in the desired locations. The first interconnection layer on top of the first dielectric layer may comprise any of the plurality of materials, including but not limited to, silver, copper, aluminum, gold, nickel, conductive polymers, conductive metal oxides, graphene, and carbon nanotubes and may be patterned into any shape and size using ink jet printing. The second dielectric layer on top of the first interconnection layer may comprise any liquid dielectric material solution, such as SUB, that may be hardened through the use of any of the plurality of curing methods, including but not limited to, heating; exposing to UV radiation; exposing to high power, short light pulses; or air drying. The forming of the second dielectric layer may comprise: utilizing alignment marks on the substrate for determining position; ink-jet printing the liquid dielectric material solution on top of the first interconnection layer in a desired pattern to create interconnection holes in desired locations; and hardening the second dielectric layer to permanently retain the interconnection holes in the desired locations. The second interconnection layer on top of the second dielectric layer may comprise any of the plurality of materials, including but not limited to, silver, copper, aluminum, gold, nickel, conductive polymers, conductive metal oxides, graphene, and carbon nanotubes and may be patterned into any shape and size using ink jet printing.

This process of depositing dielectric layers with interconnection holes and patterning interconnection layers may be repeated as many times in order to achieve complete interconnection on the substrate.

Another aspect of the present invention provides a method of manufacturing multilayer printed electronic systems, including, a substrate; alignment marks patterned on the substrate; a first electronic device layer printed on the substrate; a first dielectric layer with interconnection holes deposited on top of the first electronic device layer; a first interconnection layer on top of the first dielectric layer with holes filled with a conductive material; a second dielectric layer printed on top of the first interconnection layer with interconnection holes; a second printed electronic device layer printed on top of the second dielectric layer; and a second interconnection layer printed on top to interconnect the electronic components in the first and the second printed electronic device layers.

The substrate may comprise any rigid or flexible material, such as metal, a printed circuit board, plastic, wood, glass, semiconductor wafer, paper, or clothing. The flexible substrate may be in the form of a sheet or in the form of a roll. The substrate may comprise electronic circuitry on the backside, embedded within, or on top of the substrate, wherein the electronic circuitry is configured to transmit electrical signals. The substrate may comprise complete integrated optoelectronic circuitry on the backside, embedded within, or on top of the substrate, wherein the optoelectronic circuitry is configured to transmit both electrical and optical signals. Electronic devices may be developed on top of the substrate using printing techniques. In the present invention, the alignment marks on the substrate may comprise metal, dyes, color pigments, etc. which turn opaque upon hardening and may be patterned into any shape and size. The first dielectric layer on top of the first electronic layer may comprise any liquid dielectric material solution, such as SU8, that may be hardened through the use of any of the plurality of curing methods, including but not limited to, heating; exposing to UV radiation; exposing to high power short light pulses; or air drying. The forming of the first dielectric layer may comprise: utilizing alignment marks on the substrate for determining position; ink jet printing the liquid dielectric material solution in a desired pattern on the substrate to create interconnection holes in desired locations; and hardening the first dielectric layer to permanently retain the interconnection holes in the desired locations. The first interconnection layer on top of the first dielectric layer may comprise any of the plurality of materials, including but not limited to, silver, copper, aluminum, gold, nickel, conductive polymers, conductive metal oxides, graphene, and carbon nanotubes and may be patterned into any shape and size using ink jet printing. The second dielectric layer on top of the second printed electronic device layer may comprise any liquid dielectric material solution, such as SU8, that can be hardened through the use of any of the plurality of curing methods, including but not limited to, heating; exposing to UV radiation; exposing to high power, short light pulses; or air drying. The forming of the second dielectric layer may comprise: utilizing alignment marks on the substrate for determining position; ink jet printing the liquid dielectric material solution on top of the first interconnection layer in order to create interconnection holes in desired locations; and hardening the second dielectric layer to permanently retain the interconnection holes in the desired locations. The second printed electronic device layer on top of the second dielectric layer may be developed using printing techniques. The method of manufacturing the second printed electronic device layer on top of the second dielectric layer may comprise: utilizing alignment marks on the substrate for determining position; and depositing and curing different materials to form the printed electronic device system. The second interconnection layer on top of the second printed electronic device layer may comprise any of the plurality of materials, including but not limited to, silver, copper, aluminum, gold, nickel, conductive polymers, conductive metal oxides, graphene, and carbon nanotubes and may be patterned into any shape and size using ink jet printing. The process of developing printed electronic components; depositing dielectric layers with interconnection holes; and ink jet printing an interconnection layer may be repeated as many times in order to achieve multilayer printed electronic system on the substrate.

Other objectives and advantages of the present invention will become apparent from the following descriptions, taken in connection with the accompanying drawings, wherein, by way of illustration and example, embodiments of the present invention are disclosed.

### III. BRIEF DESCRIPTION OF THE DRAWINGS

The drawings constitute a part of this specification and include exemplary embodiments of the present invention, which may be embodied in various forms. The drawings described herein are for illustrative purposes only of selected embodiments and not of all possible implementations, and are not intended to limit the scope of the present disclosure in any way. It is to be understood that in some instances, various aspects of the present invention may be shown exaggerated or enlarged to facilitate an understanding of the invention.

A more complete and thorough understanding of the present invention and benefits thereof may be acquired by referring to the following description together with the accompanying drawings, in which like reference numbers indicate like features, and wherein:

FIGS. 1A to 1E are cross sectional views of the manufacturing process of multilayer interconnects, in accordance with some embodiments.

FIGS. 2A to 2G are cross sectional views of the manufacturing process of a multilayer printed electronic system, in accordance with some embodiments.

FIG. 3 is a block diagram illustrating a method for manufacturing one or more multilayer electrical interconnects, in accordance with some embodiments.

### IV. DETAILED DESCRIPTION

Detailed descriptions of the preferred embodiments are provided herein. It is to be understood, however, that the present invention may be embodied in various forms. The specific details disclosed herein are not to be interpreted as limiting, but rather as a basis for the claims and as representative basis for teaching one skilled in the art to employ the present invention in virtually any appropriately detailed system, structure, or manner.

In all the accompanying drawings, same numerals are used within each figure to represent the same or similar materials, and redundant descriptions are omitted.

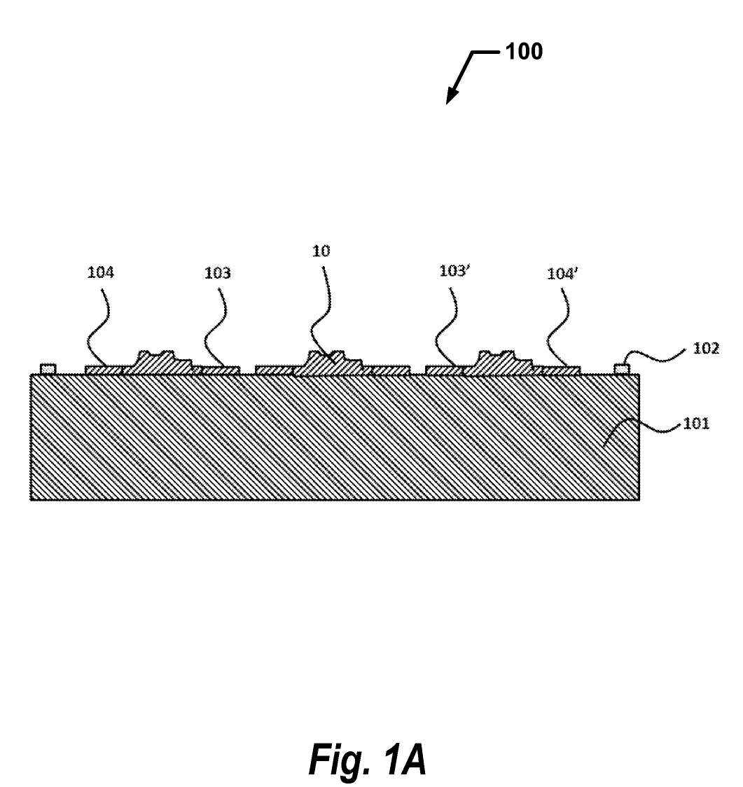

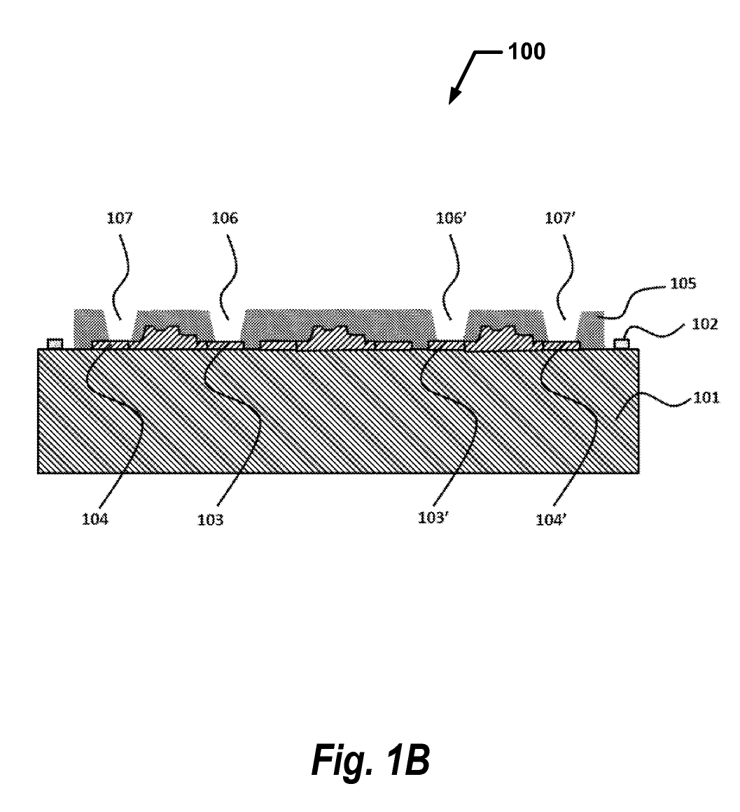

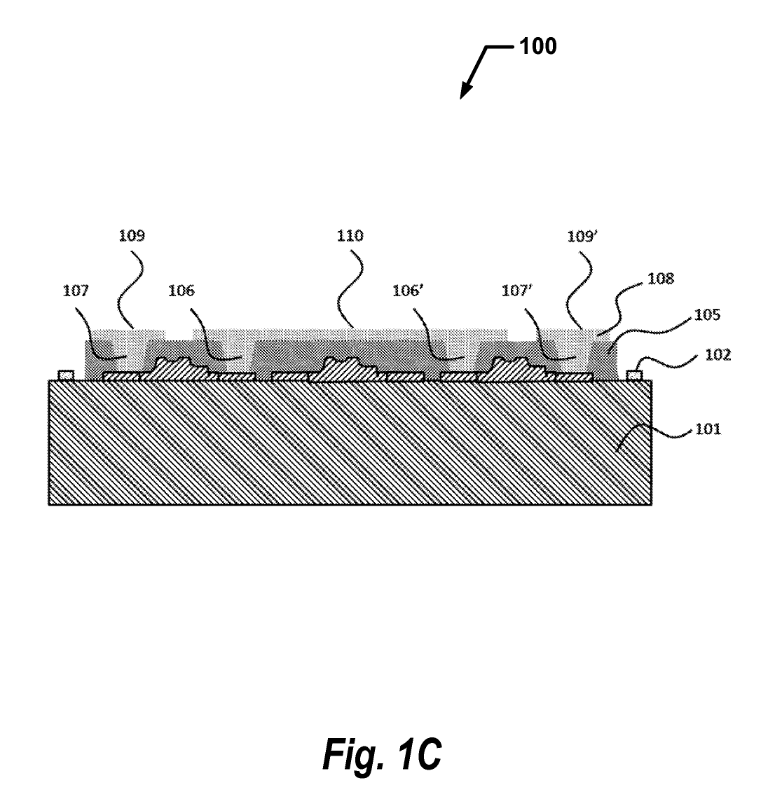

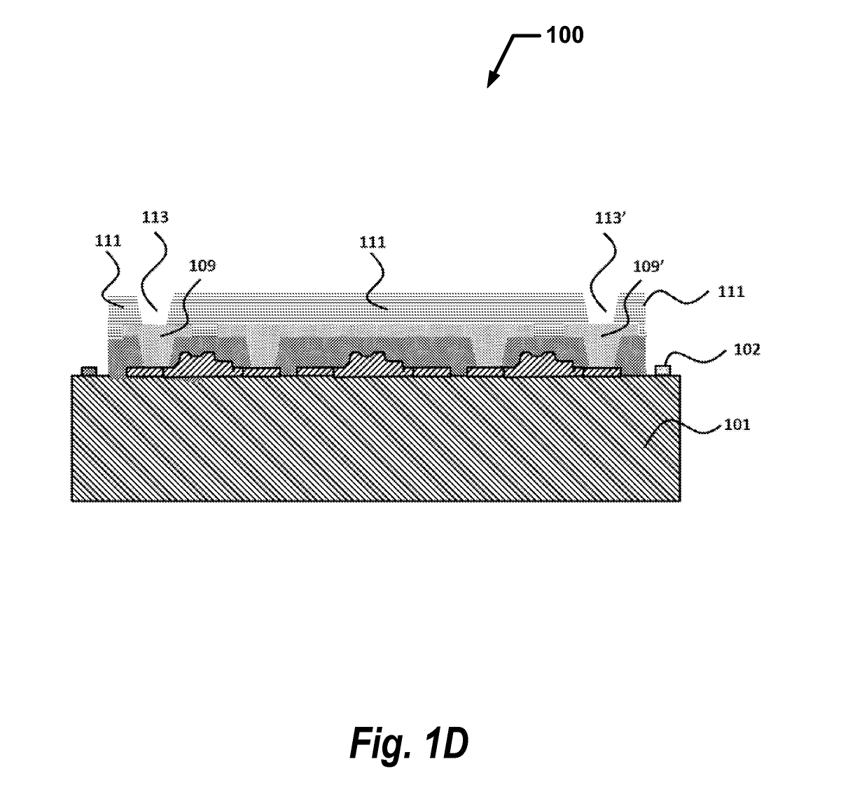

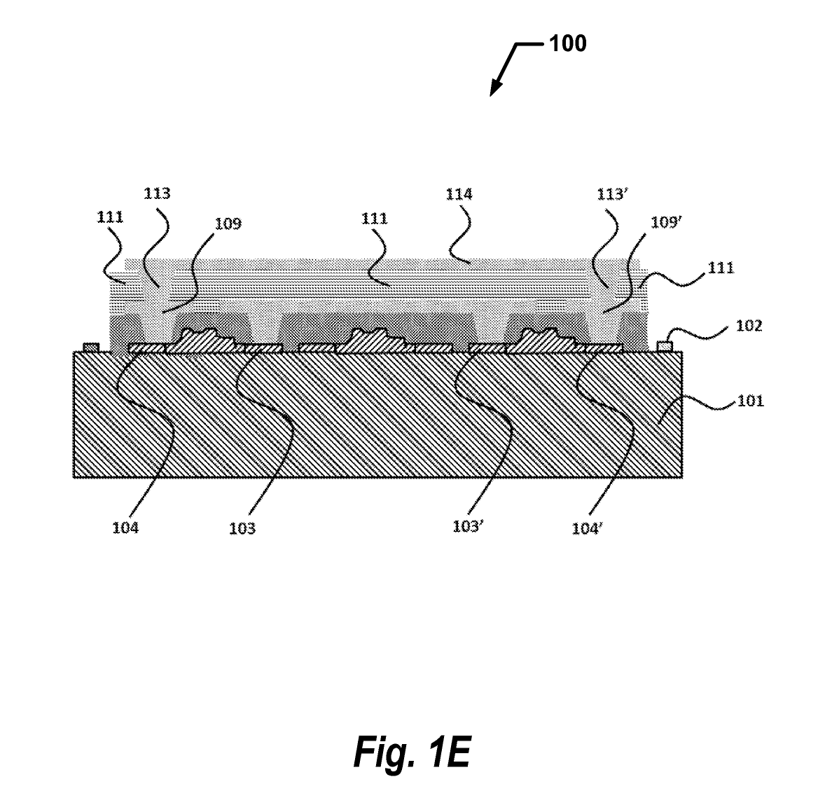

FIGS. 1A to 1E show the manufacturing process of electrical interconnects in a multilayer scheme 100 according to one embodiment of the present invention.

Referring initially to FIG. 1A, the cross sectional view of a substrate 101 is shown. The substrate material may be rigid or flexible, and may be made of metal, plastic, wood, glass, semiconductor, paper, clothing, etc. Moreover, the substrate may comprise a printed circuit board comprising electrical circuits carrying electrical signals on the front side, embedded within, or on the backside of the substrate. The substrate may also comprise optoelectronic circuits carrying optical signals on the front side, embedded within, or on the backside of the substrate. For the sole purpose of illustration, the first electronic layer containing the electronic components 10 and the alignment marks 102 are shown on top of the substrate. The example shown herein is used to illustrate the method for interconnecting contact pads 103 and 104 with contact pads 103′ and 104′, respectively. It is to be noted that the method disclosed herein may be used to interconnect any contact pads across the layer.

First, as shown in FIG. 1B, a first dielectric material 105, such as SU8, is ink-jet printed on top of the first electronic layer and cured. One such ink jet printer is a Fujifilm Dimatix Materials Printer (DMP-2800). The printer utilizes a piezoelectric cartridge to jet material onto the desired area on the substrate. The range of materials that may be ink jetted is broad and depends on the material viscosity. The viscosity should range between 10 and 12 cPs (1.0×10² to 1.2×10² Pa·s) and the surface tension should range between 28 and 33 dynes/cm (0.028 to 0.033 N/m) at operating temperature. This type of a non-contact printing method can easily be extended to a roll-to-roll process. In order to determine the position for printing on top of the first electronic layer, the alignment marks 102 are detected using an optical alignment system, and the position for printing is determined with respect to the position of the detected alignment marks. The printed first dielectric layer 105 is designed to include interconnection holes 106, 106′, 107, and 107′, such that the interconnection holes appear directly on top of contact pads 103, 103′, 104, and 104′, respectively. The first dielectric layer may be cured through the use of any of the plurality of curing methods, including but not limited to, heating; exposing to UV radiation; exposing to high power short light pulses; air drying.

Second, as shown in FIG. 1C, a first interconnection layer 108 is ink jet printed on top of the first dielectric layer 105. The first interconnection layer may comprise any of the plurality of materials, including but not limited to, silver, copper, aluminum, gold, nickel, conductive polymers, conductive metal oxides, graphene, and carbon nanotubes and may be patterned into any shape and size. In order to determine the position for printing on top of the first dielectric layer, the alignment marks 102 are detected using an optical alignment system, and the position for printing is determined with respect to the position of the detected alignment marks. The first interconnection layer is designed to fill and connect interconnection holes 106 and 106′ with interconnection line 110, and to just fill the interconnection holes 107 and 107′, to form contact pads 109 and 109′, respectively, in preparation for the next layer of printing. The first interconnection layer may be cured through the use of any of the plurality of curing methods, including but not limited to, heating; exposing to UV radiation; exposing to high power short light pulses; air drying.

Third, as shown in FIG. 1D, a second dielectric material 111, such as SU8, is printed on top of the first interconnection layer and cured. In order to determine the position for printing on top of the first interconnection layer, the alignment marks 102 are detected using an optical alignment system, and the position for printing is determined with respect to the position of the detected alignment marks. The second dielectric layer 111 comprises interconnection holes 113 and 113′, such that the interconnection holes appear directly on top of contact pads 109 and 109′, respectively. The second dielectric layer may be cured through the use of any of the plurality of curing methods, including but not limited to, heating; exposing to UV radiation; exposing to high power short light pulses; air drying.

Fourth, as shown in FIG. 1E, a second interconnection layer 114 is ink-jet printed on top of the second dielectric layer 111 and cured. The second interconnection layer may comprise any of the plurality of materials, including but not limited to, silver, copper, aluminum, gold, nickel, conductive polymers, conductive metal oxides, graphene, and carbon nanotubes and may be patterned into any shape and size using ink jet printing. In order to determine the position for printing on top of the second dielectric layer, the alignment marks 102 are detected using an optical alignment system, and the position for printing is determined with respect to the position of the detected alignment marks. The second interconnection layer is designed to fill and connect interconnection holes 113 and 113′, with interconnection line 114. The second interconnection layer may be cured through the use of any of the plurality of curing methods, including but not limited to, heating; exposing to UV radiation; exposing to high power short light pulses; air drying.

Thus, using this method of manufacturing multilayer interconnects, interconnection between contact pads 103 and 103′ and 104 and 104′, is achieved. Additional interlaced layers of dielectric layers and interconnection layers may be ink jet printed to create additional interconnection lines.

The multilayer interconnected system 100 formed in this way may be manufactured on any substrate material, and over large physical areas not possible using conventional approaches. The utilization of ink jet printing, enables deposition of material only at intended locations on the substrate, thereby eliminating wastage of expensive dielectric and conductive materials. The method disclosed herein also eliminates the use of material removal using wet or dry etching, thus, further preventing material wastage. Moreover, the utilization of solution processing techniques makes the disclosed invention roll-to-roll compatible, thus lending itself to low cost, high rate manufacturing.

The present invention is illustrated more fully by way of an example. It should be noted, however, that this example in no way limits the scope of the invention.

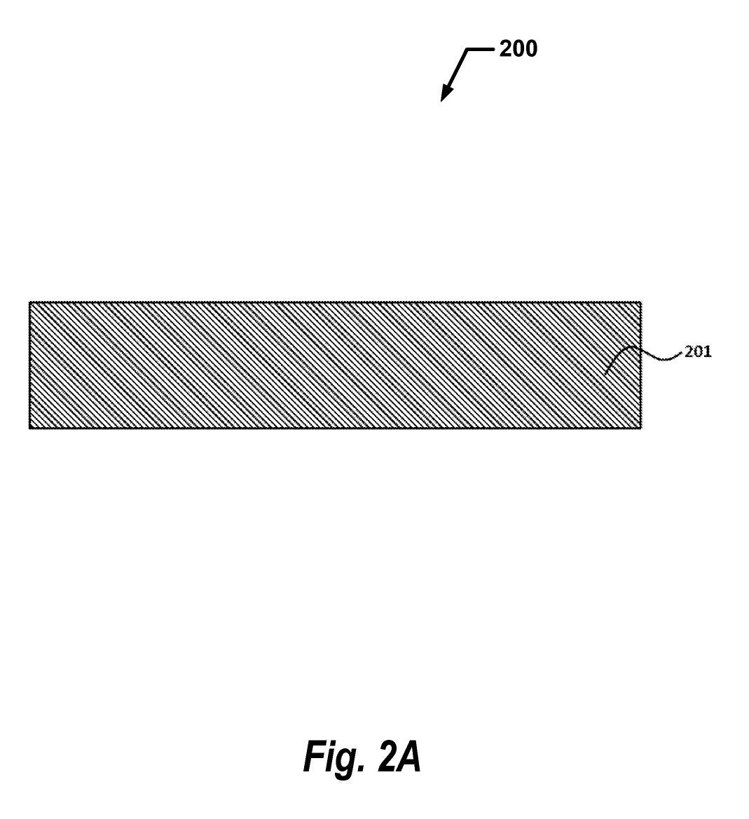

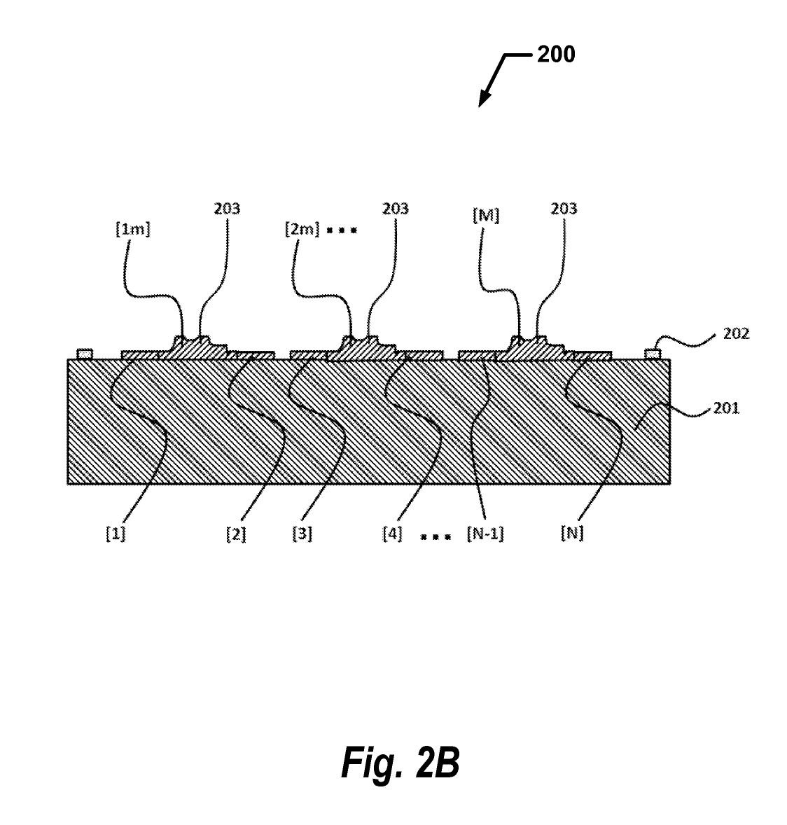

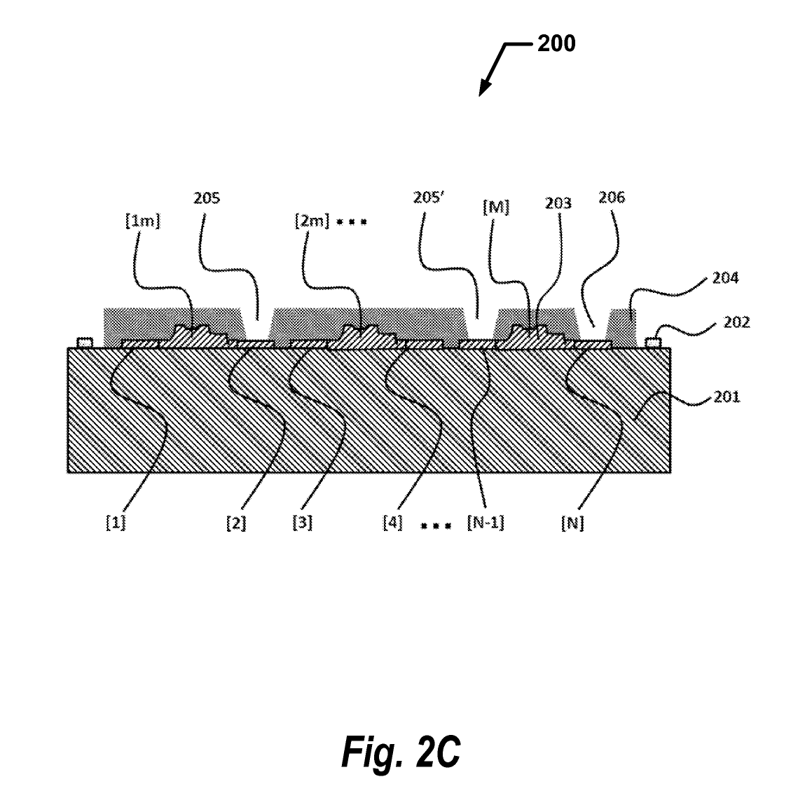

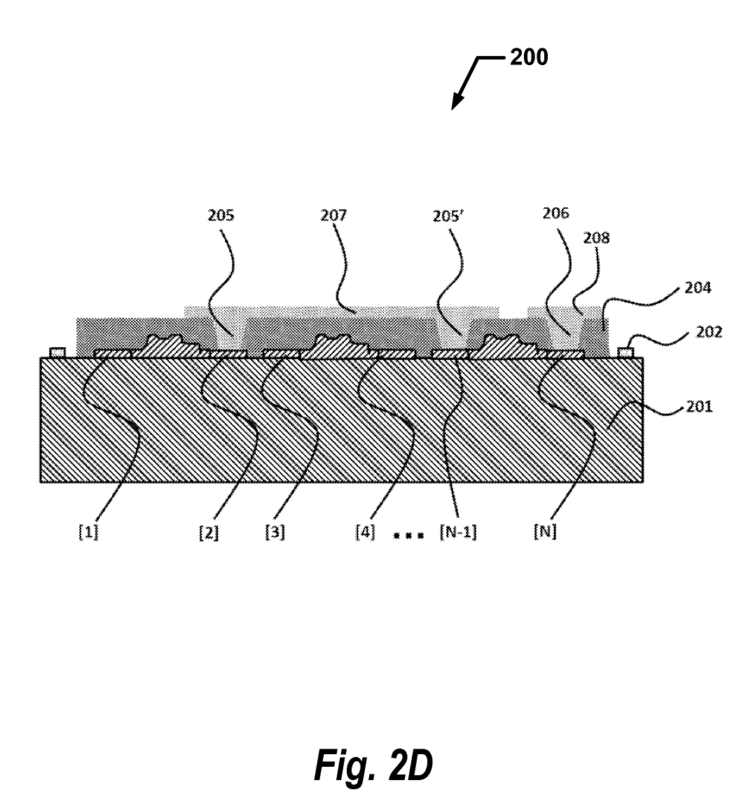

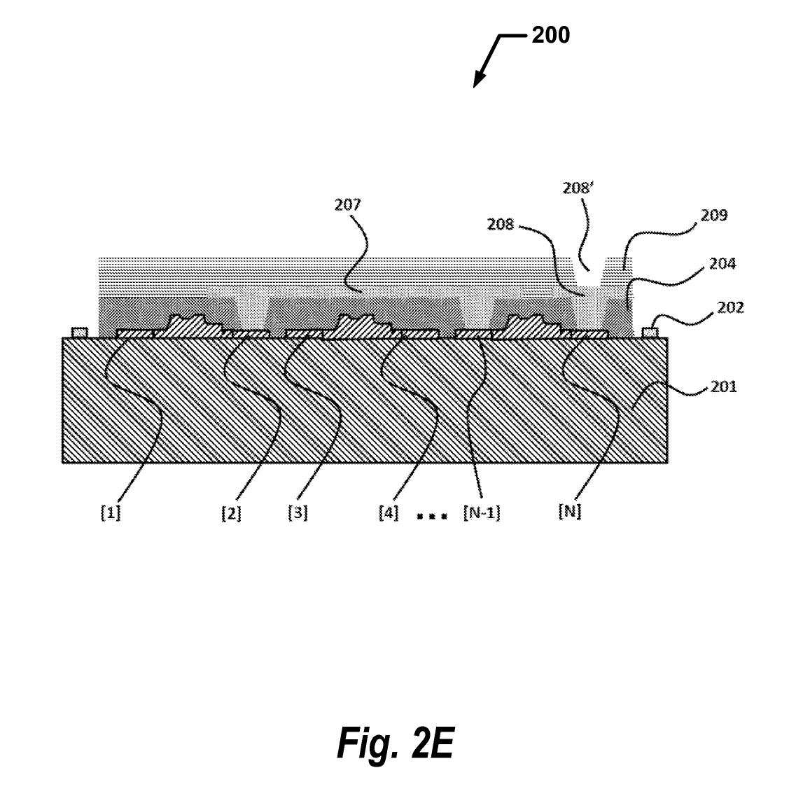

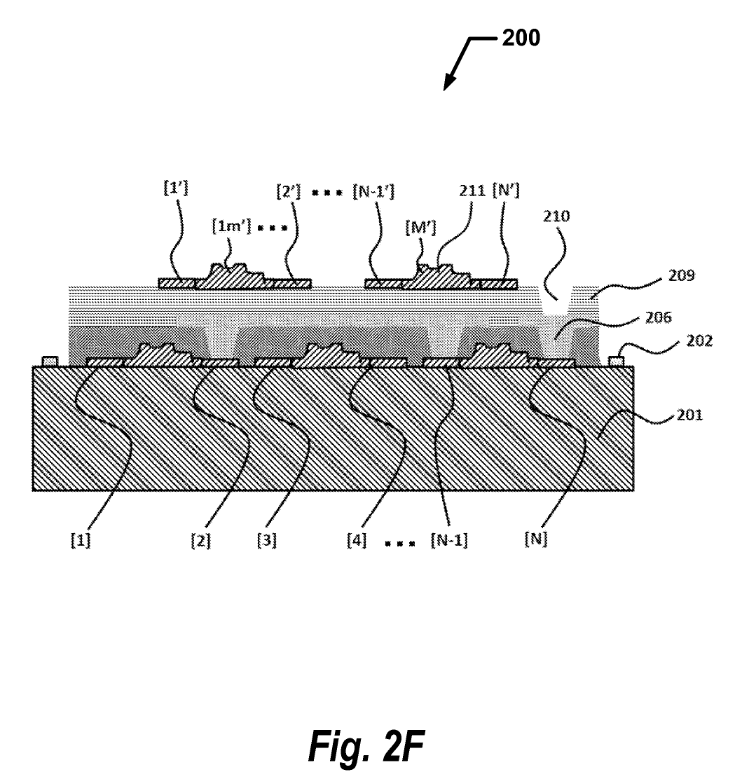

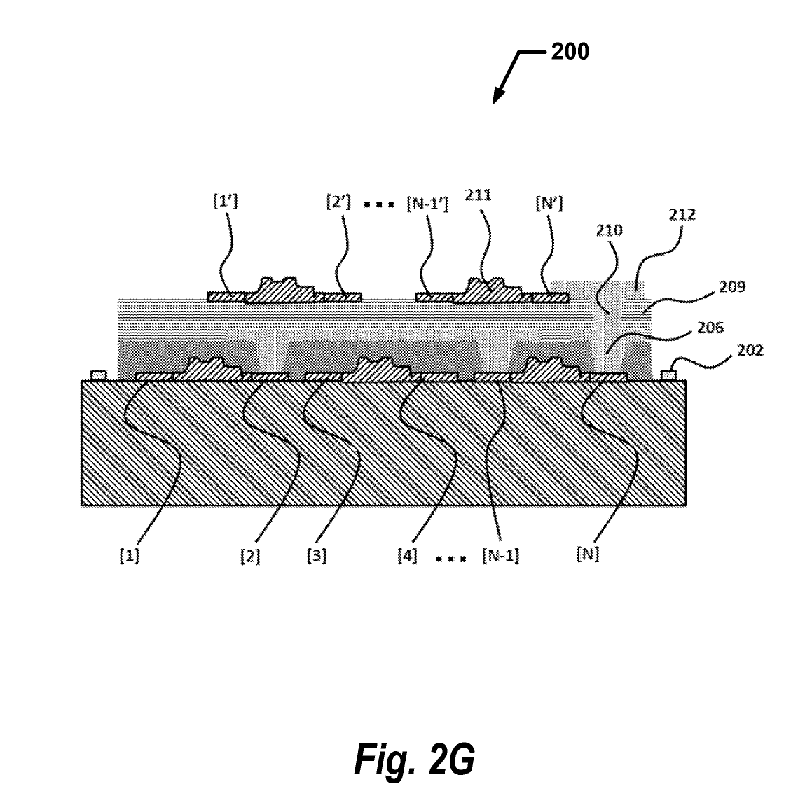

FIGS. 2A to 2G show cross sectional views of the manufacturing process of a multilayer printed electronic system 200 according to one embodiment of the present invention.

First, as shown in FIG. 2A, a substrate 201 is chosen for the device system. The substrate material may be rigid or flexible, and may be made of metal, plastic, wood, glass, semiconductor, paper, clothing, etc. Moreover, the substrate may comprise a printed circuit board comprising electrical circuits carrying electrical signals on the front side, embedded within, or on the backside of the substrate. The substrate may also comprise optoelectronic circuits carrying optical signals on the front side, embedded within, or on the backside of the substrate.

Second, as shown in FIG. 2B, alignment marks 202 are ink jet printed on the substrate and cured in order to aid in the subsequent processing steps. The alignment marks may comprise metals, dyes, color pigments, etc. which turn opaque upon hardening and may be patterned into any shape and size. One such ink jet printer is a Fujifilm Dimatix Materials Printer (DMP-2800). The printer utilizes a piezoelectric cartridge to jet material onto the desired area on the substrate. The range of materials that may be ink-jetted is broad and depends on the material viscosity. The viscosity should range between 10 and 12 cPs (1.0×10² to 1.2×10² Pa·s) and the surface tension should range between 28 and 33 dynes/cm (0.028 to 0.033 N/m) at operating temperature. This type of a non-contact printing method can easily be extended to a roll-to-roll process. Next, the first electronic device layer containing [1m] to [M] printed electronic components 203, with contact pads [1] to [N], is developed using any of the plurality of conventional methods available for manufacturing electronics. In order to determine the position for printing the first electronic device layer on the substrate, the alignment marks 202 are detected using an optical alignment system, and the position for printing is determined with respect to the position of the detected alignment marks. The alignment marks and the layers comprising the electronic components may be cured using any of the plurality of curing methods, including but not limited to, heating; exposing to UV radiation; exposing to high power, short light pulses; or air drying.

Third, as shown in FIG. 2C, the first dielectric material 204, such as SU8, is ink jet printed on top of the first electronic device layer and cured. In order to determine the position for printing on top of the first electronic device layer, the alignment marks 202 are detected using an optical alignment system, and the position for printing is determined with respect to the position of the detected alignment marks. The printed first dielectric layer 204 is designed to include interconnection holes 205, 205′, and 206, such that the interconnection holes appear directly on top of selective contact pads [2], [N-1], and [N], respectively. Note that the interconnection holes may arbitrarily be opened on top of any contact pad. The first dielectric layer may be cured through the use of any of the plurality of curing methods, including but not limited to, heating; exposing to UV radiation; exposing to high power short light pulses; air drying.

Fourth, as shown in FIG. 2D, a first interconnection layer is ink-jet printed on top of the first dielectric layer 204 and cured. The first interconnection layer may comprise any of the plurality of materials, including but not limited to, silver, copper, aluminum, gold, nickel, conductive polymers, conductive metal oxides, graphene, and carbon nanotubes and may be patterned into any shape and size. In order to determine the position for printing on top of the first dielectric layer, the alignment marks 202 are detected using an optical alignment system, and the position for printing is determined with respect to the position of the detected alignment marks. The first interconnection layer is designed to fill and connect interconnection holes 205 and 205′, using interconnection line 207, and to just fill the interconnection hole 206 to form contact pad 208, in preparation for the next layer of printing. The first interconnection layer may be cured through the use of any of the plurality of curing methods, including but not limited to, heating; exposing to UV radiation; exposing to high power short light pulses; air drying.

Fifth, as shown in FIG. 2E, a second dielectric material 209, such as SU8, is printed on top of the first interconnection layer and cured. In order to determine the position for printing on top of the first interconnection layer, the alignment marks 202 are detected using an optical alignment system, and the position for printing is determined with respect to the position of the detected alignment marks. The second dielectric layer comprises interconnection hole 208′, such that the interconnection hole appears directly on top of contact pad 208. The second dielectric layer may be cured through the use of any of the plurality of curing methods, including but not limited to, heating; exposing to UV radiation; exposing to high power short light pulses; air drying.

Sixth, as shown in FIG. 2F, the second electronic device layer containing [1m'] to [M′] printed electronic components 211, with contact pads [1′] to [N′], is developed using any of the plurality of conventional methods available for manufacturing electronics. In order to determine the position for printing the second electronic device layer on the substrate, the alignment marks 202 are detected using an optical alignment system, and the position for printing is determined with respect to the position of the detected alignment marks. The layers comprising the electronic components may be cured using any of the plurality of curing methods, including but not limited to, heating; exposing to UV radiation; exposing to high power short light pulses; or air drying.

Finally, as shown in FIG. 2G, a second interconnection layer 212 is ink jet printed on top of the second dielectric layer 209 and cured. The second interconnection layer may comprise any of the plurality of materials, including but not limited to, silver, copper, aluminum, gold, nickel, conductive polymers, conductive metal oxides, graphene, and carbon nanotubes and may be patterned into any shape and size using ink jet printing. In order to determine the position for printing on top of the second dielectric layer, the alignment marks 202 are detected using an optical alignment system, and the position for printing is determined with respect to the position of the detected alignment marks. The second interconnection layer is designed to fill the interconnection hole 210, and connect contact pads [N] and [N′]. The second interconnection layer may be cured through the use of any of the plurality of curing methods, including but not limited to, heating; exposing to UV radiation; exposing to high power short light pulses; air drying.

Thus, using this method of manufacturing, a multilayer interconnected printed electronic system is manufactured. Additional interlaced layers of dielectric layers and interconnection layers may be ink jet printed to create additional interconnection lines.

The multilayer interconnected system 200 formed in this way may be manufactured on any substrate material and over large physical areas not possible using conventional approaches. The utilization of ink jet printing, enables deposition of material only at intended locations on the substrate, thereby eliminating wastage of expensive dielectric and conductive materials. The method disclosed herein also eliminates the use of material removal using wet or dry etching, thus, further preventing material wastage. Moreover, the utilization of solution processing techniques makes the disclosed invention roll-to-roll compatible, thus lending itself to low cost, high rate manufacturing.

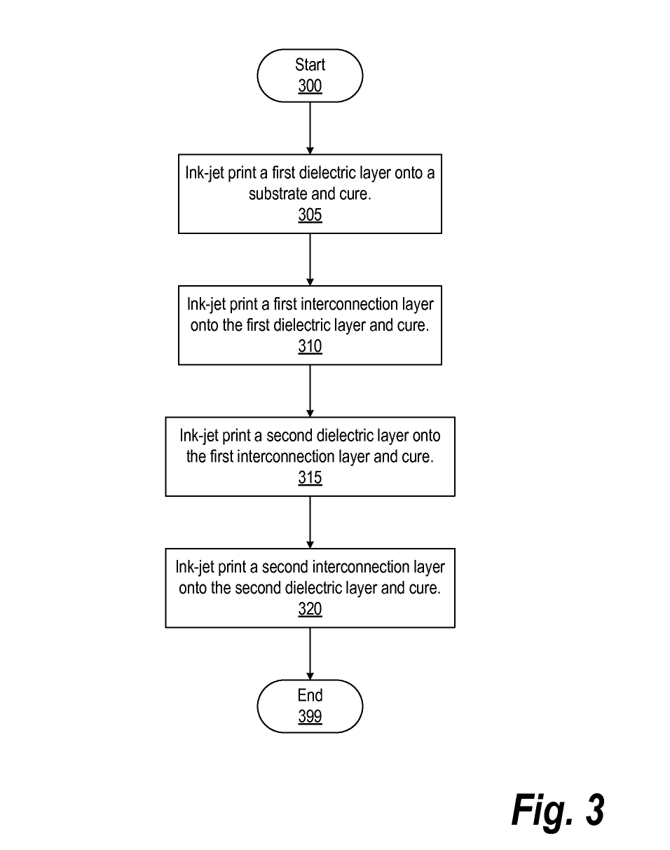

FIG. 3 is a block diagram illustrating a method for manufacturing one or more multilayer electrical interconnects, in accordance with some embodiments.

Processing begins at 300 whereupon, at block 305, a first dielectric layer is ink jet printed onto a substrate and cured. The substrate may comprise one or more electronic or optoelectronic devices on the top of the substrate, embedded within the substrate, or on the backside of the substrate. At block 310, a first interconnection layer is ink jet printed onto the first dielectric layer and cured. At block 315, a second dielectric layer is ink jet printed onto the first interconnection layer and cured. At block 320, a second interconnection layer is ink-jet printed onto the second dielectric layer and cured. Processing subsequently ends at 399. Additional ink jet printing of dielectric layers and interconnection layers may be printed in order to create additional interconnects between the one or more electronic or optoelectronic devices.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed within the following claims.

1. A method for manufacturing multilayer electrical interconnects comprising:
ink jet printing a first dielectric layer on a substrate, wherein the substrate comprises one or more electronic or optoelectronic devices and one or more alignment marks;
ink jet printing a first interconnection layer on the first dielectric layer;
ink-jet printing a second dielectric layer on the first interconnection layer; and
ink jet printing a second interconnection layer on the second dielectric layer.

2. The method of claim 1, wherein ink jet printing the first dielectric layer comprises:
determining the position of the alignment marks on the substrate;
depositing a first liquid dielectric material on the substrate to form one or more vias through the first liquid dielectric material, wherein the one or more vias through the first liquid dielectric material allow access to the one or more electronic or optoelectronic devices; and
curing the first liquid dielectric material, wherein curing the first liquid dielectric material comprises irradiating the first liquid dielectric material with UV, heating the first liquid dielectric material, exposing the first liquid dielectric material to high power, short light pulses, and/or air drying the first liquid dielectric material.

3. The method of claim 1, wherein ink jet printing the first interconnection layer comprises:
determining the position of the alignment marks on the substrate;
depositing a first liquid conductive material on the first dielectric layer to form one or more interconnections between the one or more electronic or optoelectronic devices; and
curing the first liquid conductive material, wherein curing the first liquid conductive material comprises irradiating the first liquid conductive material with UV, heating the first liquid conductive material, exposing the first liquid conductive material to high power, short light pulses, and/or air drying the first liquid conductive material.

4. The method of claim 1, wherein ink jet printing the second dielectric layer comprises:
determining the position of the alignment marks on the substrate;
depositing a second liquid dielectric material on the first interconnection layer to form one or more vias through the second liquid dielectric material, wherein the one or more vias through the second liquid dielectric material allow access to the first interconnection layer; and
curing the second liquid dielectric material, wherein curing the second liquid dielectric material comprises irradiating the second liquid dielectric material with UV, heating the second liquid dielectric material, exposing the second liquid dielectric material to high power, short light pulses, and/or air drying the second liquid dielectric material.

5. The method of claim 1, wherein ink jet printing the second interconnection layer comprises:
determining the position of the alignment marks on the substrate;
depositing a second liquid conductive material on the second dielectric layer to form one or more interconnections between the one or more electronic or optoelectronic devices; and
curing the second liquid conductive material, wherein curing the second liquid conductive material comprises irradiating the second liquid conductive material with UV, heating the second liquid conductive material, exposing the second liquid conductive material to high power, short light pulses, and/or air drying the second liquid conductive material.

6. The method of claim 1, further comprising ink jet printing one or more dielectric layers interlaced with one or more interconnection layers on the second interconnection layer and/or the second dielectric layer.

7. A method for manufacturing multilayer printed electronic devices comprising:
ink jet printing one or more alignment marks on a substrate;
printing a first electronic device layer on the substrate, wherein the first electronic device layer comprises one or more electronic or optoelectronic devices;
ink-jet printing a first dielectric layer on top of the first electronic device layer and the substrate;
ink jet printing a first interconnection layer on top of the first dielectric layer;
ink jet printing a second dielectric layer on top of the first dielectric layer and the first interconnection layer;
printing a second electronic device layer on top of the second dielectric layer, wherein the second electronic device layer comprises additional one or more electronic or optoelectronic devices; and
ink-jet printing a second interconnection layer on top of the second dielectric layer;

8. The method of claim 7, wherein ink jet printing the one or more alignment marks comprises:
depositing a liquid material on the substrate, wherein the liquid material is at least one of: a dye, a pigment, and metal nanoparticles; and
curing the liquid material, wherein curing the liquid material comprises irradiating the liquid material with UV, heating the liquid material, exposing the liquid material to high power, short light pulses, and/or air drying the liquid material.

9. The method of claim 7, wherein ink-jet printing the first dielectric layer comprises:
determining the position of the alignment marks on the substrate;
depositing a first liquid dielectric material on the first electronic device layer and the substrate to form one or more vias through the first liquid dielectric material, wherein the one or more vias through the first liquid dielectric material allow access to the one or more electronic or optoelectronic devices; and
curing the first liquid dielectric material, wherein curing the first liquid dielectric material comprises irradiating the first liquid dielectric material with UV, heating the first liquid dielectric material, exposing the first liquid dielectric material to high power, short light pulses, and/or air drying the first liquid dielectric material.

10. The method of claim 7, wherein ink-jet printing the first interconnection layer comprises:
determining the position of the alignment marks on the substrate;
depositing a first liquid conductive material on the first dielectric layer to form one or more interconnections between the one or more electronic or optoelectronic devices; and
curing the first liquid conductive material, wherein curing the first liquid conductive material comprises irradiating the first liquid conductive material with UV, heating the first liquid conductive material, exposing the first liquid conductive material to high power, short light pulses, and/or air drying the first liquid conductive material.

11. The method of claim 7, wherein ink-jet printing the second dielectric layer comprises:
determining the position of the alignment marks on the substrate;
depositing a second liquid dielectric material on the first interconnection layer to form one or more vias through the second liquid dielectric material, wherein the one or more vias through the second liquid dielectric material allow access to the first interconnection layer; and
curing the second liquid dielectric material, wherein curing the second liquid dielectric material comprises irradiating the second liquid dielectric material with UV, heating the second liquid dielectric material, exposing the second liquid dielectric material to high power, short light pulses, and/or air drying the second liquid dielectric material.

12. The method of claim 7, wherein ink jet printing the second interconnection layer comprises:
determining the position of the alignment marks on the substrate;
depositing a second liquid conductive material on the second dielectric layer to form one or more interconnections between the one or more electronic or optoelectronic devices and the additional one or more electronic or optoelectronic devices; and
curing the second liquid conductive material, wherein curing the first liquid conductive material comprises irradiating the first liquid conductive material with UV, heating the second liquid conductive material, exposing the second liquid conductive material to high power, short light pulses, and/or air drying the second liquid conductive material.

13. The method of claim 7, further comprising ink jet printing one or more dielectric layers interlaced with one or more interconnection layers on the second interconnection layer, the second electronic device layer, and/or the second dielectric layer.

14. A method for manufacturing multilayer electrical interconnects comprising:
ink jet printing one or more alignment marks on a substrate, wherein the substrate comprises one or more electronic or optoelectronic devices and one or more alignment marks;
ink jet printing a first dielectric layer on the substrate;
ink jet printing a first interconnection layer on the first dielectric layer;
ink-jet printing a second dielectric layer on the first interconnection layer; and
ink jet printing a second interconnection layer on the second dielectric layer.

15. The method of claim 14, wherein ink-jet printing the one or more alignment marks comprises:
depositing a liquid material on the substrate, wherein the liquid material is at least one of: a dye, a pigment, and metal nanoparticles; and
curing the liquid material, wherein curing the liquid material comprises irradiating the liquid material with UV, heating the liquid material, exposing the liquid material to high power, short light pulses, and/or air drying the liquid material.

16. The method of claim 14, wherein ink-jet printing the first dielectric layer comprises:
determining the position of the alignment marks on the substrate;
depositing a first liquid dielectric material on the substrate to form one or more vias through the first liquid dielectric material, wherein the one or more vias through the first liquid dielectric material allow access to the one or more electronic or optoelectronic devices; and
curing the first liquid dielectric material, wherein curing the first liquid dielectric material comprises irradiating the first liquid dielectric material with UV, heating the first liquid dielectric material, exposing the first liquid dielectric material to high power, short light pulses, and/or air drying the first liquid dielectric material.

17. The method of claim 14, wherein ink-jet printing the first interconnection layer comprises:
determining the position of the alignment marks on the substrate;
depositing a first liquid conductive material on the first dielectric layer to form one or more interconnections between the one or more electronic or optoelectronic devices; and
curing the first liquid conductive material, wherein curing the first liquid conductive material comprises irradiating the first liquid conductive material with UV, heating the first liquid conductive material, exposing the first liquid conductive material to high power, short light pulses, and/or air drying the first liquid conductive material.

18. The method of claim 14, wherein ink-jet printing the second dielectric layer comprises:
determining the position of the alignment marks on the substrate;
depositing a second liquid dielectric material on the first interconnection layer to form one or more vias through the second liquid dielectric material, wherein the one or more vias through the second liquid dielectric material allow access to the first interconnection layer; and
curing the second liquid dielectric material, wherein curing the second liquid dielectric material comprises irradiating the second liquid dielectric material with UV, heating the second liquid dielectric material, exposing the second liquid dielectric material to high power, short light pulses, and/or air drying the second liquid dielectric material.

19. The method of claim 14, wherein ink jet printing the second interconnection layer comprises:
determining the position of the alignment marks on the substrate;
depositing a second liquid conductive material on the second dielectric layer to form one or more interconnections between the one or more electronic or optoelectronic devices; and
curing the second liquid conductive material, wherein curing the second liquid conductive material comprises irradiating the second liquid conductive material with UV, heating the second liquid conductive material, exposing the second liquid conductive material to high power, short light pulses, and/or air drying the second liquid conductive material.

20. The method of claim 14, further comprising ink jet printing one or more dielectric layers interlaced with one or more interconnection layers on the second interconnection layer and/or the second dielectric layer.
